(19) United States
(12) Patent Application Publication
(10) Pub. No.: US 2015/0255758 A1
(43) Pub. Date: Sep. 10, 2015

(54) METHOD OF BONDING DISPLAY DEVICE

(71) Applicant: Samsung Display Co., Ltd., Yongin-City (KR)

(72) Inventor: Akira Hirai, Yongin-City (KR)

(21) Appl. No.: 14/493,181

(22) Filed: Sep. 22, 2014

(30) Foreign Application Priority Data
Mar. 7, 2014 (KR) 10-2014-0027427

(51) Int. Cl. H01L 51/56; H01L 51/52

(52) U.S. Cl. CPC H01L 51/56; H01L 51/5246; H01L 51/5253; H01L 2251/5338

(57) ABSTRACT

A method of bonding a display device is disclosed. In one aspect, the method comprises forming a seal portion between a substrate, on which an emission region is foamed, and an encapsulating part mounted facing the substrate, aligning positions of the substrate and the encapsulating part in a chamber, changing a vacuum state of the chamber to an atmospheric pressure state so as apply bonding pressure to the substrate and the encapsulating part, wherein the vacuum state and the atmospheric pressure state have different pressures, and applying energy to the seal portion so as to bond the substrate and the encapsulating part.

### INCORPORATION BY REFERENCE TO ANY PRIORITY APPLICATIONS

This application claims the benefit of Korean Patent Application No. 10-2014-0027427, filed on Mar. 7, 2014, in the Korean Intellectual Property Office, the disclosure of which is incorporated herein in its entirety by reference.

### BACKGROUND

1. Field

The described technology generally relates to a method of bonding a display device.

2. Description of the Related Technology

Typically, an organic light-emitting diode (OLED) display having a thin film transistor (TFT) can be used for display devices of a mobile device, such as smartphones, digital cameras, camcorders, portable information terminals, laptop computers, tablets, and the like, and electronic and electrical products, such as TVs and the like.

The OLED display includes an OLED having a first electrode, a second electrode, and an intermediate layer interposed between the first electrode and the second electrode. The OLED displays have wide view angles, good contrast, and quick response speeds.

Recently, research is being conducted to manufacture relatively slim display devices. Flexible display devices are easy to carry and capable of being applied to devices having various shapes among the relatively slim display devices and thus have been highlighted as a next-generation display device. Flexible display devices based on OLED display technology is strongly being considered.

### SUMMARY OF CERTAIN INVENTIVE ASPECTS

One inventive aspect is a method of bonding a display device, by which uniform pressure is applied to a region where a substrate and an encapsulating part are bonded.

Another aspect is a method of bonding a display device includes: forming a seal portion between a substrate, on which an emission region is formed, and an encapsulating part mounted so as to face the substrate; aligning positions of the substrate and the encapsulating part in a chamber; applying bonding pressure to the substrate and the encapsulating part by a pressure difference obtained by changing a vacuum state of the inside of the chamber to an atmospheric pressure state; and bonding the substrate and the encapsulating part by applying energy to the seal portion between the substrate and the encapsulating part.

The seal portion can be any one selected from organic adhesive, an organic pressure sensitive adhesive, a metal film, an oxide, a sulfide, a nitride, an organic sulfur compound, and an organic silicon compound.

The bonding pressure and the energy can be applied at the same time.

The seal portion can be activated by applying the energy before or when the bonding is performed.

The energy can be applied by irradiating an energy beam to the seal portion.

The energy can be applied by heating the seal portion.

The substrate can be formed by any one selected from a glass substrate, a polymer substrate, a flexible film substrate, a metal substrate, and a composite substrate thereof.

The encapsulating part can be formed of a flexible film.

The encapsulating part can include: a base film including a polymer; and at least one inorganic layer and at least one organic layer stacked on one surface of the base film.

When the bonding pressure inside the chamber is insufficient, the bonding pressure can be raised by increasing pressure inside the chamber.

The bonding pressure can be applied to the entire substrate and the entire encapsulating part when a press jig presses a surrounding part of the substrate and the encapsulating part.

A mask having a pattern can be further mounted on the encapsulating part, and the energy can be selectively applied to the seal portion through the pattern of the mask.

The bonding pressure can be applied to the entire substrate and the entire encapsulating part when a diaphragm presses the entire substrate and the entire encapsulating part.

The diaphragm can have a size for accommodating the substrate and the encapsulating part and press an entire upper surface of the encapsulating part while the bonding pressure is being applied.

The diaphragm can be formed of a material having an elastic force.

The seal portion can be formed in a non-emission region extending outside the emission region on the substrate.

The light-emission on the substrate and the seal portion can be formed with different heights, and the encapsulating part can include a flexible film and can be directly bonded to the seal portion by using the flexibility of the flexible film to compensate for a thickness difference between the emission region and the seal portion.

The substrate can have a size from which a plurality of display devices are manufactured and can be divided into individual display devices by cutting after the bonding between the substrate and the encapsulating part is completed.

Another aspect is a method of bonding a display device that comprises forming a seal portion between a substrate, on which an emission region is formed, and an encapsulating part mounted facing the substrate. The above method further comprises aligning positions of the substrate and the encapsulating part in a chamber, changing a vacuum state of the chamber to an atmospheric pressure state so as apply bonding pressure to the substrate and the encapsulating part, wherein the vacuum state and the atmospheric pressure state have different pressures, and applying energy to the seal portion so as to bond the substrate and the encapsulating part.

In the above method, the seal portion is formed of any one selected from organic adhesive, an organic pressure sensitive adhesive, a metal film, an oxide, a sulfide, a nitride, an organic sulfur compound, an organic silicon compound, and a combination thereof.

In the above method, the bonding pressure and the energy are substantially simultaneously applied.

In the above method, the seal portion is activated by applying the energy before or when the bonding is performed.

In the above method, the energy is applied by irradiating an energy beam to the seal portion.

In the above method, the energy is applied by heating the seal portion.

In the above method, the substrate comprises any one selected from a glass substrate, a polymer substrate, a flexible film substrate, a metal substrate, and a composite substrate thereof.

In the above method, the encapsulating part comprises a flexible film.

In the above method, the encapsulating part comprises a base film comprising a polymer and at least one inorganic layer and at least one organic layer stacked on one surface of the base film.

In the above method, when the bonding pressure inside the chamber is insufficient to bond the substrate and the encapsulating part, pressure inside the chamber is raised so as to increase bonding pressure.

In the above method, the bonding pressure is applied to the entire substrate and the entire encapsulating part when a press jig presses a surrounding part of the substrate and the encapsulating part. In the above method, a mask having a pattern is further mounted on the encapsulating part, wherein the energy is selectively applied to the seal portion through the pattern.

In the above method, the bonding pressure is applied to the entire substrate and the entire encapsulating part when a diaphragm presses the entire substrate and the entire encapsulating part. In the above method, the diaphragm has a size for accommodating the substrate and the encapsulating part and presses an entire upper surface of the encapsulating part while the bonding pressure is being applied.

In the above method, the diaphragm is formed of a material having an elastic force.

In the above method, the seal portion is formed in a non-emission region extending outside the emission region on the substrate. In the above method, the emission region and the seal portion on the substrate are formed with different thicknesses, wherein the encapsulating part comprises a flexible film and is directly bonded to the seal portion by using the flexibility of the flexible film to compensate for the different thicknesses.

In the above method, a plurality of display devices are manufactured with the substrate, and wherein the substrate is cut into individual display devices after the bonding between the substrate and the encapsulating part is completed.

Another aspect is a method of bonding a display device, the method comprising forming a seal portion between a substrate and an encapsulating part, aligning positions of the substrate and the encapsulating part in a chamber, changing an amount of pressure of the chamber to an atmospheric pressure so as apply bonding pressure to the substrate and the encapsulating part, and applying energy to the seal portion so as to bond the substrate and the encapsulating part, wherein the bonding pressure and the energy are substantially simultaneously applied.

In the above method, the encapsulating part comprises a flexible film.

### BRIEF DESCRIPTION OF THE DRAWINGS

FIG. 1 is an exploded perspective view of a display device according to an embodiment.

FIG. 2 is a combined cross-sectional view of the display device of FIG. 1.

FIG. 3 is a cross-sectional view of one sub-pixel of a display unit in the display device of FIG. 1.

FIG. 4 is a block diagram of an organic light-emitting diode (OLED) of FIG. 3.

FIG. 5 is a perspective view of a flexible display device in a flat state, according to another embodiment.

FIG. 6 is a perspective view of the display device of FIG. 5 in a rolled state.

FIG. 7 is a flowchart of a method of bonding a substrate and an encapsulating part of a display panel according to an embodiment

FIG. 8 is a diagram of a first chamber for forming a seal portion on the substrate of the display panel of FIG. 7.

FIG. 9 is a diagram of a second chamber for applying pressure and energy to the display panel of FIG. 8.

FIG. 10 is a diagram of a chamber for applying pressure and energy to a display panel, according to another embodiment.

FIG. 11 is a diagram of a chamber for applying pressure and energy to a display panel, according to another embodiment.

FIG. 12 is a cross-sectional view of a display panel completely formed through a bonding method, according to an embodiment.

FIG. 13 is a magnified cross-sectional view of an encapsulating part according to an embodiment.

### DETAILED DESCRIPTION OF CERTAIN INVENTIVE EMBODIMENTS

When there is oxygen or moisture in a display device, the display device can deteriorate, the brightness thereof can be lowered, and the lifespan thereof can be shortened. Therefore, for display devices, an encapsulation technique for protecting a device from oxygen or moisture is desired.

The described technology can allow various kinds of change or modification and various changes in form, and specific embodiments will be illustrated in drawings and described in detail in the specification. However, it should be understood that the specific embodiments do not limit the inventive concept to a specific disclosing form but include every modified, equivalent, or replaced one within the spirit and technical scope of the described technology. In the following description, well-known functions or constructions are not described in detail so as not to obscure the invention with unnecessary detail.

It will be understood that although the terms “first”, “second”, etc. can be used herein to describe various components, these components should not be limited by these terms. These components are only used to distinguish one component from another.

The terminology used in the application is used only to describe specific embodiments and does not have any intention to limit the described technology. The singular forms “a,” “an” and “the” are intended to include the plural forms as well, unless the context clearly indicates otherwise. In the application, it should be understood that terms, such as ‘include’ and ‘have’, are used to indicate the existence of an implemented feature, number, step, operation, element, part, or a combination thereof without excluding in advance the possibility of the existence or addition of one or more other features, numbers, steps, operations, elements, parts, or combinations thereof.

Reference will now be made in detail to embodiments of a method of bonding a display device, examples of which are illustrated in the accompanying drawings, wherein like reference numerals refer to like elements throughout. In this regard, the present embodiments can have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list. In this disclosure, the term “substantially” includes the meanings of completely, almost completely or to any significant degree under some applications and in accordance with those skilled in the art. Moreover, “formed on” can also mean “formed over.”

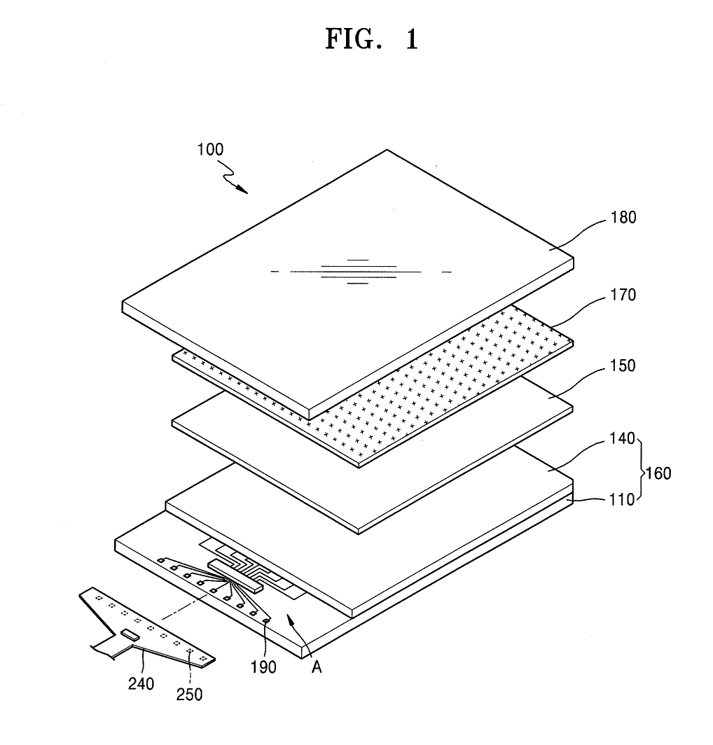

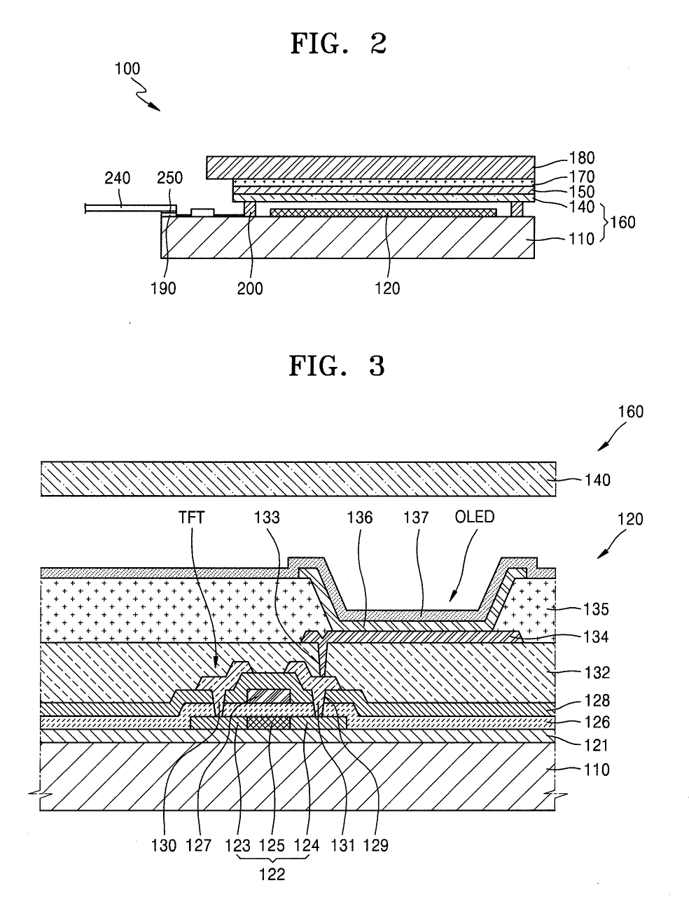

FIG. 1 is an exploded perspective view of a display device 100 according to an embodiment. FIG. 2 is a combined cross-sectional view of the display device 100 of FIG. 1.

In the current embodiment, the display device 100 is an organic light-emitting diode (OLED) display but is not limited thereto. The display device 100 can be any display device that can display an image by applying power thereto.

Referring to FIGS. 1 and 2, the display device 100 includes a display panel 160 having a substrate 110 and an encapsulating part 140 mounted on the substrate 110. A display unit 120 for realizing an image is formed on the substrate 110.

The substrate 110 can be a polymer substrate, a rigid glass substrate, a flexible film substrate, a metal substrate, or a composite substrate thereof. The encapsulating part 140 can be polymer resin or a flexible film. The encapsulating part 140 can be formed by alternately stacking an organic layer and an inorganic layer.

A seal portion 200 for sealing a region where the display unit 120 is formed is mounted on surfaces of the substrate 110 and the encapsulating part 140 which face each other. The seal portion 200 is formed along the edges of the facing surfaces of the substrate 110 and the encapsulating part 140.

A touch screen 150 is formed on the encapsulating part 140. The touch screen 150 can be an on-cell touch screen panel (TSP) having a touch screen pattern on the encapsulating part 140. The touch screen 150 can be on the encapsulating part 140 as one body but is not limited thereto.

A polarizing plate 170 is formed on the touch screen 150. The polarizing plate 170 can prevent external light from being reflected by the display unit 120 to the user.

A window cover 180 for protecting the display device 100 is mounted on the polarizing plate 170. The window cover 180 can be formed of rigid glass.

The substrate 110 has a region A extending from the encapsulating part 140 and exposed to the outside. A plurality of pads 190 are separately arranged in the exposed region A along one direction of the substrate 110.

Terminals 250 of a circuit board 240 are electrically connected to the plurality of pads 190, respectively, so as to receive a signal from the outside. The circuit board 240 can be a flexible printed circuit board (FPCB).

FIG. 3 is a cross-sectional view of one sub-pixel of the display unit 120 of FIG. 1.

Referring to FIG. 3, a barrier layer 121 is formed on the substrate 110. The barrier layer 121 has an organic layer structure, an inorganic layer structure, or a structure of alternately stacking an organic layer and an inorganic layer. The barrier layer 121 can block the infiltration of oxygen or moisture into an OLED.

A thin-film transistor TFT is formed on the barrier layer 121. The TFT according to the present embodiment illustrates a top gate type thin-film transistor, but a thin-film transistor of another structure, such as a bottom gate type thin-film transistor or the like, can be provided.

A semiconductor active layer 122 is formed on the barrier layer 121. The semiconductor active layer 122 can be formed of polycrystalline silicon but it is not necessarily limited thereto. In some embodiments, the semiconductor active layer 122 can be formed of an oxide semiconductor.

For example, the oxide semiconductor can include an oxide of a material selected from the group consisting of 12-, 13-, and 14-group metallic elements, such as zinc (Zn), indium (In), gallium (Ga), tin (Sn), cadmium (Cd), germanium (Ge), and hafnium (Hf), and a combination thereof.

The semiconductor active layer 122 includes a source region 123 and a drain region 124 formed by doping N-type impurity ions or P-type impurity ions. A region between the source region 123 and the drain region 124 is a channel region 125 in which no impurities are doped.

A gate insulating layer 126 is deposited on the semiconductor active layer 122. The gate insulating layer 126 can be formed of an inorganic layer, such as silicon oxide, silicon nitride, or metal oxide, and is formed in a single-layer structure or a multiple-layer structure.

A gate electrode 127 is formed on the gate insulating layer 126. The gate electrode 127 can be formed of a single- or multi-layer of gold (Au), silver, (Ag), copper (Cu), nickel (Ni), platinum (Pt), palladium (Pd), aluminum (Al), molybdenum (Mo), or chromium (Cr), or an alloy, such as an Al:neodymium (Nd) alloy or a Mo:tungsten (W) alloy.

An interlayer insulating layer 128 is formed on the gate electrode 127. The interlayer insulating layer 128 can be formed with an inorganic layer of silicon oxide, silicon nitride, or the like. The interlayer insulating layer 128 can include an organic layer.

A source electrode 130 and a drain electrode 131 are formed on the interlayer insulating layer 128. Contact holes 129 can be foamed by selectively removing portions of the gate insulating layer 126 and the interlayer insulating layer 128, wherein the source electrode 130 is electrically connected to the source region 123 through one contact hole 129, and the drain electrode 131 is electrically connected to the drain region 124 through the other contact hole 129.

A protective layer (passivation layer and/or planarization layer) 132 is formed on the source electrode 130 and the drain electrode 131. The protective layer 132 can protect and planarized the TFT therebelow. The protective layer 132 can be formed of, for example, an organic material, such as acryl or the like, or an inorganic material, such as silicon nitride (SiNₓ) or the like. The protective layer 132 can be formed as a single- or multi-layer.

The OLED can be formed on the TFT.

To form the OLED, a first electrode 134 corresponding to a pixel electrode is electrically connected to the source electrode 130 or the drain electrode 131 through a contact hole 133.

The first electrode 134 functions as an anode among electrodes included in the OLED and can be formed of various conductive materials. The first electrode 134 can be formed as a transparent electrode or a reflective electrode according to the application.

For example, when the first electrode 134 is used as a transparent electrode, the first electrode 134 can be formed of indium tin oxide (ITO), indium zinc oxide (IZO), zinc oxide (ZnO), indium oxide (In₂O₃), or the like, and when the first electrode 134 is used as a reflective electrode, a reflective layer can be formed of Ag, magnesium (Mg), Al, Pt, Pd, Au, Ni, Nd, iridium (Ir), Cr, or a compound thereof, and ITO, IZO, ZnO, In₂O₃, or the like can be formed on the reflective layer.

A pixel-defining layer (PDL) 135 is formed on the protective layer 132 to at least partially cover the edge of the first electrode 134. The PDL 135 defines an emission region of each sub-pixel by surrounding the edge of the first electrode 134.

The PDL 135 can be formed of an organic material or an inorganic material.

For example, the PDL 135 can be formed of an organic material, such as polyimide (PI), polyamide, benzocyclobutene (BCB), acryl resin, phenol resin, or the like, or an inorganic material, such as SiNₓ. The PDL 135 can be formed as a single- or multi-layer, i.e., can be variously changed.

An intermediate layer 136 is formed on the first electrode 134 at a portion exposed by etching a portion of the PDL 135. The intermediate layer 136 can be formed by a vapor deposition process.

According to the present embodiment, although the intermediate layer 136 is patterned to correspond to each sub-pixel, i.e., the patterned first electrode 134, this is for convenience of description to describe a configuration of a sub-pixel, and various embodiments thereof can be implemented.

The intermediate layer 136 can be formed of a low-molecular organic material or a high-molecular organic material.

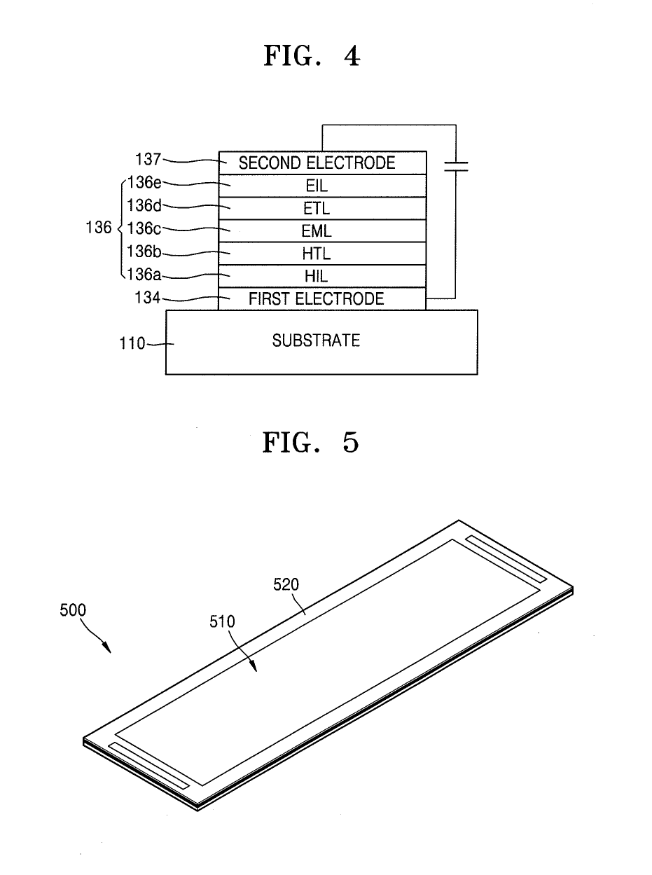

For example, as shown in FIG. 4, the intermediate layer 136 includes an organic emission layer (EML) 136c and can further include at least one selected from the group consisting a hole injection layer (HIL) 136a, a hole transport layer (HTL) 136b, an electron transport layer (ETL) 136d, and an electron injection layer (EIL) 136e. In some embodiments, the intermediate layer 136 includes the organic EML 136c, but is not limited thereto and can further include other various function layers.

Referring to FIG. 3, a second electrode 137 corresponding to a common electrode of the OLED is formed on the intermediate layer 136. The second electrode 137 can be formed as a transparent electrode or a reflective electrode, as well as the first electrode 134.

The first electrode 134 and the second electrode 137 can be insulated from each other by the intermediate layer 136. When a voltage is applied between the first electrode 134 and the second electrode 137, the intermediate layer 136 can emit visible light to thereby display an image which is recognizable by a user.

The second electrode 137 can be formed as a transparent electrode or a reflective electrode, as well as the first electrode 134.

When the second electrode 137 is used as a transparent electrode, a metal having a small work function, i.e., lithium (Li), calcium (Ca), lithium fluoride (LiF)/Ca, LiF/Al, Al, Mg, or a compound thereof, can be deposited on the intermediate layer 136, and an auxiliary electrode formed of a transparent electrode forming material, such as ITO, IZO, ZnO, In₂O₃, or the like, can be formed thereon.

When the second electrode 137 is used as a reflective electrode, the second electrode 137 is formed by depositing Li, Ca, LiF/Ca, LiF/Al, Al, Mg, or a compound thereof on the whole surface of the intermediate layer 136.

When the first electrode 134 is formed as a transparent electrode or a reflective electrode, the first electrode 134 can be formed in a shape corresponding to an aperture of each sub-pixel. The second electrode 137 can be formed by depositing a transparent electrode or a reflective electrode on the whole surface of a display region.

Alternatively, the second electrode 137 can be formed in various patterns instead of vapor deposition over the whole surface of the display region. The first electrode 134 and the second electrode 137 can be stacked in opposite positions to the ones shown.

The encapsulating part 140 can be combined with the OLED. The encapsulating part 140 is formed so as to protect the OLED and other thin layers from external moisture, oxygen, and the like.

The encapsulating part 140 can be polymer resin or a flexible film. The encapsulating part 140 can be formed by alternately stacking an organic layer and an inorganic layer.

In some embodiments, the display device 100 corresponds to a rigid display device but can be manufactured as a flexible display device.

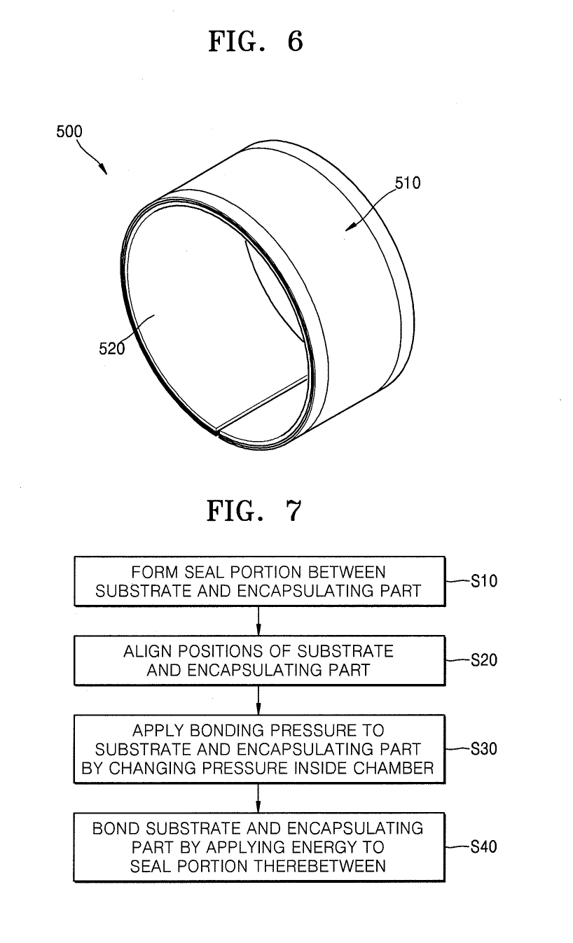

FIG. 5 is a perspective view of a flexible display device 500 in a flat state, according to another embodiment. FIG. 6 is a perspective view of the flexible display device 500 of FIG. 5 in a rolled state.

Referring to FIGS. 5 and 6, the flexible display device 500 can include a flexible display panel 510 for displaying an image and a flexible holder 520 on which the flexible display panel 510 is mounted.

The flexible display panel 510 can include not only a flexible substrate on which a display unit for displaying an image is mounted but also various films, such as an encapsulating part for covering the flexible substrate, a touch screen, a polarizing plate, and the like, can be mounted.

The flexible display device 500 allows a user to view an image in various states, such as a flat state, a curved state, and the like, or to easily store or carry the flexible display device 500.

To this end, the flexible display device 500 includes the flexible substrate and a encapsulating part including a flexible film, wherein a region for bonding the flexible substrate and the encapsulating part exists on facing surfaces of the flexible substrate and the encapsulating part.

In a display device, such as the display device 100 of FIG. 1 or the display device 500 of FIG. 5, a substrate included in a display panel and an encapsulating part for covering the substrate are bonded to each other. That is, the substrate and the encapsulating part are firmly bonded by applying a certain pressure and energy to a seal portion in a region where the substrate and the encapsulating part are bonded.

A method of bonding the substrate and the encapsulating part will now be described in more detail.

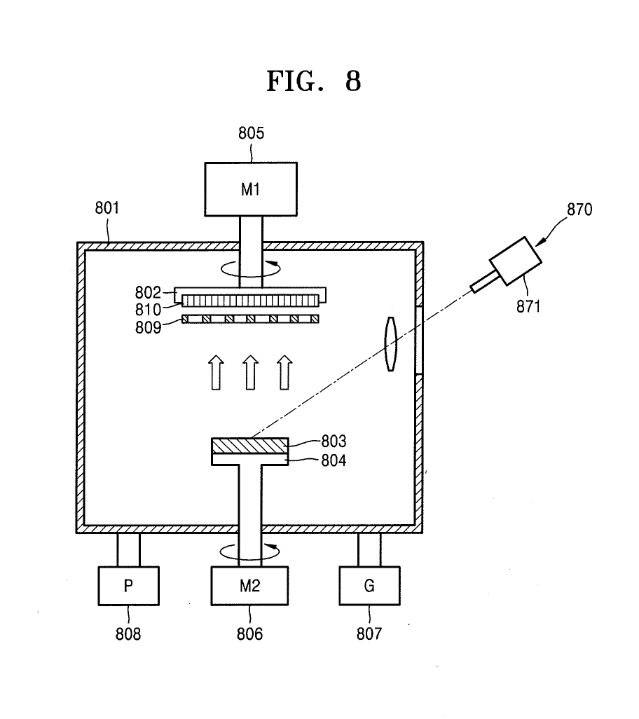

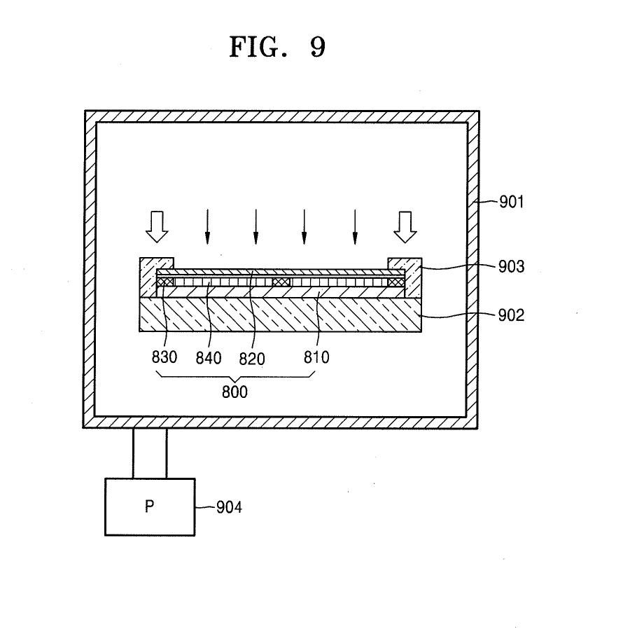

FIG. 7 is a flowchart of a method of bonding a substrate 810 and an encapsulating part 820 of a display panel 800 according to an embodiment. FIG. 8 is a diagram of a first chamber 801 for forming a seal portion 830 on the substrate 810 of the display panel 800. FIG. 9 is a diagram of a second chamber 901 for applying pressure and energy to the display panel 800 of FIG. 8.

Referring to FIGS. 7 and 8, in operation S10, the seal portion 830 (see FIG. 9) is formed between the substrate 810 and the encapsulating part 820 (see FIG. 9).

It is described as an example that the seal portion 830 is formed on the substrate 810, but the seal portion 830 is not limited thereto and can be formed on the encapsulating part 820, formed on both the substrate 810 and the encapsulating part 820, or on any region where the substrate 810 and the encapsulating part 820 are bonded to each other.

An emission region 840 (see FIG. 9) for displaying an image is formed on the substrate 810. The OLED shown in FIG. 3 is formed in the emission region 840. The seal portion 830 is formed in a non-emission region extending beyond the emission region 840.

The substrate 810 is loaded inside the first chamber 801. The substrate 810 can be a polymer substrate, a rigid glass substrate, a flexible film substrate, a metal substrate, or a composite substrate thereof.

The first chamber 801 provides a deposition space and can be a vacuum chamber. A substrate holder 802, on which the substrate 810 is mounted, and a target holder 804, on which a target or target material or deposition material 803 for deposition is mounted, are mounted inside the first chamber 801.

In the present embodiment, although the substrate holder 802 is arranged at an upper side of the first chamber 801, and the target holder 804 is arranged at a lower side of the first chamber 801, the positions thereof are not necessarily limited thereto.

A mask 809 having a pattern for selectively forming the seal portion 830 can be further mounted on the substrate 810. A heater (not shown) for heating the substrate 810 can be further mounted on the substrate holder 802 so that a deposition material is easily deposited on a deposited surface of the substrate 810.

The substrate holder 802 supports the substrate 810 inside of the first chamber 801. The substrate holder 802 can vacuum-adsorb an opposite surface of the deposited surface of the substrate 810 or support the substrate 810 by another clamp member. The substrate holder 802 can be rotated in one direction by a first motor 805.

The target holder 804 can fixate the target 803 for deposition which can be formed of a raw material to be deposited on the substrate 810. In the present embodiment, the target 803 for deposition can be formed of a raw material of the seal portion 830, e.g., any material selected from organic adhesive, an organic pressure sensitive adhesive, a metal film, an oxide, a sulfide, a nitride, an organic sulfur compound, and an organic silicon compound.

The target holder 804 can be rotated in the one direction or the opposite direction by a second motor 806.

A laser irradiation device 870 is mounted outside the first chamber 801. The laser irradiation device 870 irradiates a laser beam to the target 803 for deposition. The laser beam generated by a laser generation unit 871 can be irradiated to the target 803 for deposition with high energy. When the laser beam is irradiated to the target 803 for deposition, plasma is formed, thereby generating nanoparticles from the target 803 for deposition.

A reaction gas provided to form the plasma particles can be argon (Ar) gas or the like that is an active gas. A gas supply part 807 for supplying the reaction gas is coupled to the first chamber 801.

A vacuum pump 808 for forming vacuum is mounted on the first chamber 801.

The particles generated from the target 803 for deposition by a laser deposition method as described above are scattered to the substrate 810, thereby forming the seal portion 830 on the substrate 810.

In the present embodiment, although the laser deposition method has been described to form the seal portion 830 as an example, the substrate 810 and the encapsulating part 820 can be bonded by forming the seal portion 830 therebetween by various methods besides the laser deposition method.

For example, the substrate 810 and the encapsulating part 820 can be bonded by forming, by a screen printing method, the raw material of the seal portion 830 in a region where the substrate 810 and the encapsulating part 820 are bonded and annealing the raw material of the seal portion 830.

As another method, organic adhesive, an organic pressure sensitive adhesive, or the like can be formed in the region where the substrate 810 and the encapsulating part 820 are bonded to each other.

The substrate 810 and the encapsulating part 820 can be bonded by i) forming a monolayer of molecules having a functional group reacting with both the substrate 810 and the encapsulating part 820, ii) pressing the facing surfaces of the substrate 810 and the encapsulating part 820 so as to contact each other, and iii) applying energy, such as heating, ultraviolet irradiation, or the like, so as to induce a chemical reaction.

As described above, when a monolayer of a molecular adhesive or a coupling agent such as silane or the like is formed, the monolayer reacts and is fused according to energy irradiation. For the energy irradiation, laser beams having various wavelengths, ultraviolet irradiation using a mask, and a flashlight can be used according to the contents of a reaction.

As another method, a thin film, such as silicon (Si), can be plasma-deposited in the region where the substrate 810 and the encapsulating part 820 are bonded to each other.

The substrate 810 and the encapsulating part 820 can be bonded by forming an Si thin film in the bonding region and activating the Si thin film by a high-vacuum ion beam. Since the bonding is achieved by a Si—Si inorganic thin film, a sufficient barrier property against moisture and gases can be secured.

When activating the seal portion 830, energy, such as an ion beam, a laser beam, an ultraviolet ray, or the like, can be applied to the seal portion 830 before or in the bonding.

As another method, without separately forming the seal portion 830, the substrate 810 and the encapsulating part 820 can be bonded by forming the outermost layers of the substrate 810 and the encapsulating part 820 as inorganic layers.

As described above, the method of bonding the substrate 810 and the encapsulating part 820 is not limited to any method.

Referring to FIGS. 7 and 9, in operation S20, positions of the substrate 810, on which the sealing portion 830 is formed, and the encapsulating part 820 are aligned in a vertical direction.

The encapsulating part 820 can include a flexible film having the barrier property. The encapsulating part 820 is formed so as to protect the OLED and the like from external moisture, oxygen, and the like.

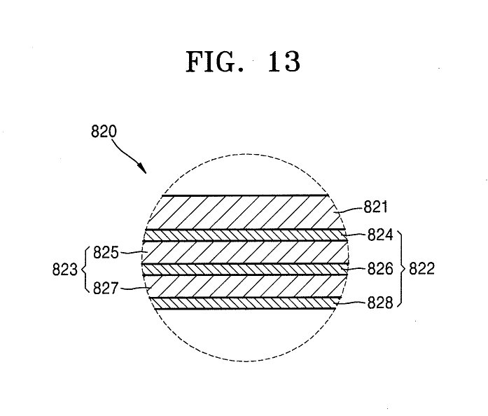

The encapsulating part 820 includes a base film 821, as shown in FIG. 13.

The base film 821 can be formed of polyethylene naphthalate (PEN), polyethylene terephthalate (PET), polycarbonate (PC), polyethersulfone (PES), transparent polyimide (PI), polyarylate (PAR), polycyclic olefin (PCO), cross-linkable epoxy, cross-linkable urethane film, or the like.

At least one inorganic layer 822 and at least one organic layer 823 are stacked on one surface of the base film 821. In the present embodiment, the inorganic layer 822 includes a first inorganic layer 824, a second inorganic layer 826, and a third inorganic layer 828, and the organic layer 823 includes a first organic layer 825 and a second organic layer 827.

Each of the first, second, and third inorganic layers 824, 826, and 828 can be formed of silicon oxide (SiO₂), silicon nitride (SiNₓ), aluminum oxide (Al₂O₃), titanium oxide (TiO₂), zirconium oxide (ZrOₓ), zinc oxide (ZnO), or the like.

Each of the first and second organic layers 825 and 827 can be formed of epoxy, PI, PET, PC, polyethylene, polyacrylate, or the like.

The third inorganic layer 828, which is the outermost inorganic layer, i.e., a layer located to face the substrate 810, can be formed as an inorganic layer so as to prevent intrusion of moisture into the OLED.

A deposition method of the encapsulating part 820 having a structure as described above can include a vacuum dry process, such as sputtering, chemical vapor deposition (CVD), synthesis by deposition of a monomer, or the like, a wet process, such as coating, modification, or printing of a precursor solution, or the like.

The encapsulating part 820 is a film having a good barrier property and has a water vapor transmission rate (WVTR) of about 10⁻² g/m²·day or less. The WVTR of the encapsulating part 820 varies according to a display device for which the encapsulating part 820 is used.

For example, the WVTR of the encapsulating part 820 can be about 10⁻³ g/m²·day for electronic paper, about 10⁻⁴ g/m²·day for organic electroluminescent (EL) lighting, and about 10⁻⁶ g/m²·day for an organic EL display element. As such, the encapsulating part 820 can be variously used according to the width of a seal portion, a functional film stacked on the encapsulating part 820, and a cover window of a display device.

The emission region 840 in which the OLED is formed and another portion, e.g., the seal portion 830, can be formed with different thicknesses.

In addition, the emission region 840 has a structure in which a portion where the OLED is formed and a portion where the OLED is not formed are repeated, i.e., it can form an uneven structure. Accordingly, the OLED can be protected and the substrate 810 can be supported by covering the entire or at least a portion of the emission region 840 with transparent resin or a pressure sensitive adhesive, or forming a plurality of transparent spacers.

Referring back to FIG. 9, in operation S20, positions of the substrate 810 and the encapsulating part 820 are aligned in the vertical direction.

The second chamber 901 can be substantially the same as the first chamber 801, or a chamber provided to bond the substrate 810 and the encapsulating part 820 after the seal portion 830 is formed on the substrate 810, in an in-line process for continuous work. The second chamber 901 includes a pump 904 and can switch a mode from a vacuum state to an atmospheric pressure state.

A stage 902 is mounted in the second chamber 901, and the substrate 810 is mounted on the stage 902. The seal portion 830 is formed in the non-emission region of the substrate 810.

The encapsulating part 820 is aligned on the substrate 810.

When energy to be applied to bond the substrate 810 and the encapsulating part 820 cannot be applied through the substrate 810, for example, activation according to an ion beam and the like can be previously performed before the bonding.

The display panel 800 can have a size large enough to form a plurality of display devices at the same time for mass production. For example, on the substrate 810, the display panel 800 has a layout of n columns×m rows, and the encapsulating part 820 has a layout of (n+1) columns×(m+1) rows. The seal portion 830 can be formed for each display panel.

In operation S30, after the position alignment is completed, bonding pressure is applied to the substrate 810 and the encapsulating part 820.

When the bonding pressure is applied, a press jig 903 presses the display panel 800. That is, the press jig 903 is mounted at a surrounding part of the display panel 800 along an edge of the encapsulating part 820, and the press jig 903 presses the display panel 800 with a certain pressure so that the encapsulating part 820 surface-contacts the substrate 810.

To apply the bonding pressure when the press jig 903 presses the display panel 800, a degree of vacuum inside the second chamber 901 having the pump 904 can be reduced so as to change a vacuum state to an atmospheric pressure state. When the inside of the second chamber 901 is in the atmospheric pressure state, pressure of about 1.03 kgf/cm² is substantially uniformly applied to the entire display panel 800.

When the bonding pressure applied to the display panel 800 is not sufficient, the bonding pressure can be raised by increasing pressure inside the second chamber 901.

When the bonding pressure is applied, the thickness difference between the emission region 840, in which the OLED is formed, and the seal portion 830 can be compensated for by the flexibility of the encapsulating part 820, thereby directly bonding the encapsulating part 820 onto the seal portion 830.

The seal portion 830 does not have a support member such as a spacer or the like. When a spacer is mounted on the OLED, when the vacuum inside the second chamber 901 is slowly leaked, the encapsulating part 820 can be pressed by the atmospheric pressure so as to contact the substrate 810.

As such, by changing the pressure inside the second chamber 901 from the vacuum state to the atmospheric pressure state, the bonding pressure can be uniformly applied to the entire substrate 810 and the entire encapsulating part 820. In addition, the applied pressure can be raised by increasing pressure inside the second chamber 901.

Furthermore, by both annealing and the pressure increase, a Young's modulus E of the encapsulating part 820 can be lowered so as to prevent deformation and making the bonding easy. By locally annealing the encapsulating part 820, the encapsulating part 820 can be easily controlled. The annealing can be performed by instantaneously increasing a temperature by scanning a laser beam or irradiation of an infrared lamp or a halogen lamp.

In operation S40, after pressing the display panel 800, the substrate 810 and the encapsulating part 820 are bonded to each other by applying energy to the seal portion 830 therebetween.

The bonding pressure to be applied to the substrate 810 and the encapsulating part 820 and the energy to be applied to the seal portion 830 between the substrate 810 and the encapsulating part 820 can be substantially simultaneously applied.

Energy, such as an ultraviolet ray, a laser beam, an electron beam, or a particle beam such as an ion beam, is applied to the seal portion 830 from an energy source mounted on an upper part in the second chamber 901, as shown by arrows in FIG. 9. Alternatively, thermal energy can be applied by heating the seal portion 830.

When the energy is applied to the seal portion 830, a bonding force between the substrate 810 and the seal portion 830 and between the encapsulating part 820 and the seal portion 830 can increase, thereby increasing a bonding strength between the substrate 810 and the encapsulating part 820.

As described above, the display panel 800 can be firmly bonded by substantially uniformly applying the bonding pressure to a region bonded due to a pressure difference through a change of the inside of the second chamber 901 from the vacuum state to the atmospheric pressure state or a pressing state and applying energy.

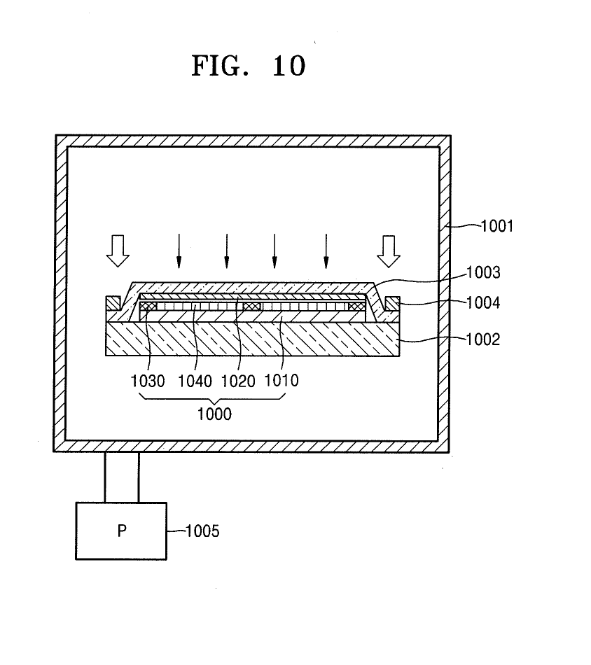

FIG. 10 is a diagram of a chamber 1001 for applying pressure and energy to a display panel 1000, according to another embodiment

Hereinafter, only certain parts of the above-described embodiments are extracted and described for simplicity.

Referring to FIG. 10, a substrate 1010 is mounted on a stage 1002 prepared inside the chamber 1001. An emission region 1040 is formed on the substrate 1010, and a seal portion 1030 is formed between neighboring emission regions 1040.

The substrate 1010 can be a large-sized substrate for mass production, and a plurality of emission regions 1040 corresponding to individual display devices, respectively, can be formed on the substrate 1010.

An encapsulating part 1020 is aligned on the substrate 1010.

Bonding pressure is applied to the substrate 1010 and the encapsulating part 1020 by changing pressure inside the chamber 1001.

A diaphragm 1003 is mounted on the display panel 1000. When the bonding pressure is applied, the diaphragm 1003 presses the display panel 1000. That is, the diaphragm 1003 has a size for accommodating both the substrate 1010 and the encapsulating part 1020 and generally presses the entire upper surface of the encapsulating part 1020.

A press jig 1004 is further mounted on an edge portion of the diaphragm 1003 so as to support the diaphragm 1003.

The diaphragm 1003 can be formed of a material having good elasticity, e.g., elastomer or rubber. When the diaphragm 1003 has good elasticity, the seal portion 1030 between the substrate 1010 and the encapsulating part 1020 can be sufficiently pressed.

In order to apply the bonding pressure when the diaphragm 1003 presses the display panel 1000, a degree of vacuum inside the chamber 1001 having a pump 1005 is reduced from a vacuum state to an atmospheric pressure state. In the atmospheric pressure state, the bonding pressure can be substantially uniformly applied to the entire display panel 1000. When the bonding pressure applied to the display panel 1000 is not sufficient, the bonding pressure can be raised by increasing the pressure.

When a bank is mounted on the diaphragm 1003 at a portion corresponding to the seal portion 1030, the seal portion 1030 can be more effectively pressed than that without the bank.

When the bonding pressure is applied, the substrate 1010 and the encapsulating part 1020 are bonded to each other by applying energy to the seal portion 1030 between the substrate 1010 and the encapsulating part 1020.

The energy applied to the seal portion 1030 can be thermal energy even when the diaphragm 1003 is opaque. When a laser beam, an ultraviolet ray, a lamp, or the like is used, the diaphragm 1003 can be transparent. In this case, the diaphragm 1003 can be formed of transparent silicon rubber.

Through the above-described bonding process, the substrate 1010 and the encapsulating part 1020 can be firmly bonded.

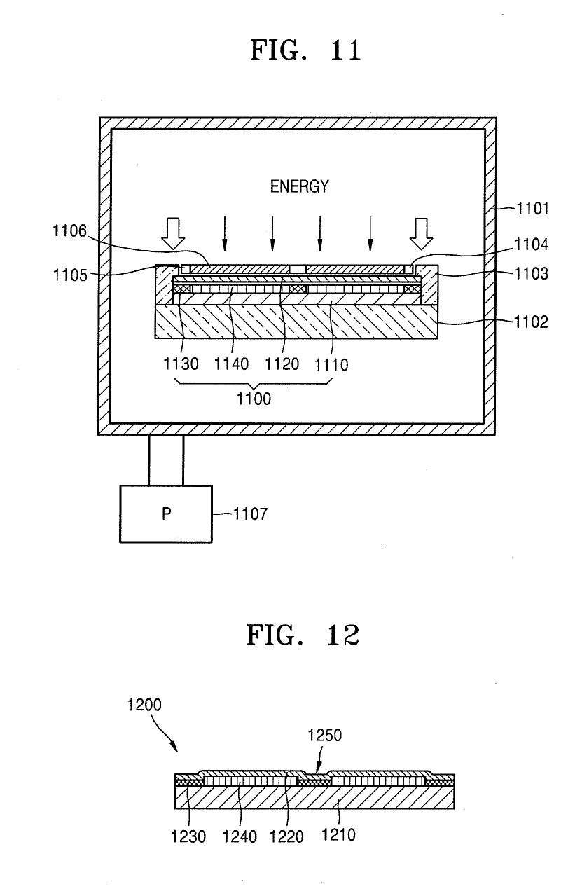

FIG. 11 is a diagram of a chamber 1101 for applying pressure and energy to a display panel 1100, according to another embodiment.

Referring to FIG. 11, a stage 1102 is prepared inside the chamber 1001.

A substrate 1110 is mounted on the stage 1102. The substrate 1110 is a large-sized substrate and has a size from which a plurality of display devices can be manufactured together. A plurality of emission regions 1140 are formed on the substrate 1110. A seal portion 1130 is formed between neighboring emission regions 1140.

The substrate 1110 and an encapsulating part 1120 are aligned in a vertical direction.

After the alignment is completed, bonding pressure is applied to the substrate 1110 and the encapsulating part 1120 by changing pressure inside the chamber 1101.

When the bonding pressure is applied, a press jig 1103 mounted on an edge part of the display panel 1100 presses the outer surface of the encapsulating part 1120.

A mask 1104 having a certain pattern is mounted on the encapsulating part 1120. The mask 1104 includes a portion 1105 through which energy beams indicated as arrows pass and a portion 1106 by which the energy beams are blocked. The portion 1105 through which the energy beams pass corresponds in a substantially vertical direction to the seal portion 1130 interposed between the substrate 1110 and the encapsulating part 1120.

When the press jig 1103 presses the display panel 1100, a degree of vacuum inside the chamber 1101 having a pump 1107 is reduced from a vacuum state to an atmospheric pressure state. When the inside of the chamber 1101 enters the atmospheric pressure state, the bonding pressure is uniformly applied to the entire display panel 1100. A pressing treatment inside the chamber 1101 can be further performed.

When the bonding pressure is applied, the substrate 1110 and the encapsulating part 1120 are bonded to each other by applying energy to the seal portion 1130.

Since the mask 1104 is mounted on the encapsulating part 1120, when energy is applied from an energy source, the energy beams selectively pass through the portion 1105 as indicated by arrows, thereby bonding the substrate 1110 and the encapsulating part 1120.

As the energy source, a device capable of irradiating optical energy, such as laser beams or ultraviolet rays, can be used. When an ultraviolet device is used, ultraviolet rays pass through the portion 1105 through which the energy beams pass, thereby hardening the seal portion 1130.

Alternatively, when a halogen lamp irradiates after forming the portion 1105 through which the energy beams pass to be transparent and forming a reflective layer at the portion 1106 by which the energy beams are blocked, a temperature at the portion 1106 by which the energy beams are blocked does not increase since the energy beams are reflected, but a temperature at the portion 1105 through which the energy beams pass increases, thereby bonding the substrate 1110 and the encapsulating part 1120.

Through the above-described bonding process, a bonding strength of the substrate 1110 and the encapsulating part 1120 can be improved.

FIG. 12 is a cross-sectional view of a display panel 1200 completely formed through a bonding method, according to an embodiment.

Referring to FIG. 12, a plurality of emission regions 1240 are formed on a substrate 1210. One emission region 1240 corresponds to an individual display device. A seal portion 1230 is formed between neighboring emission regions 1240.

An encapsulating part 1220 is bonded onto the substrate 1210. The substrate 1210 and the encapsulating part 1220 are bonded by a pressure difference occurring by changing pressure inside a chamber from a vacuum state to an atmospheric pressure state and can be firmly bonded by applying certain energy thereto.

In this case, a portion where the emission regions 1240 are formed has a height that is different from a height of the seal portion 1230, thereby forming a thickness difference part 1250 at a bonding region where the seal portion 1230 is formed. Since the encapsulating part 1220 is formed of a flexible film, even though the thickness difference part 1250 is formed, it can be easy for the encapsulating part 1220 to be directly bonded to the substrate 1210 according to the flexibility of the encapsulating part 1220.

The completed display panel 1200 is separated into individual unit display devices by a cutting process.

As described above, according to the method of bonding a display device the one or more of the above embodiments of the described technology, a substrate, on which an emission region is formed, and an encapsulating part can be bonded by applying uniform pressure thereto.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the inventive technology have been described with reference to the figures, it will be understood by those of ordinary skill in the art that various changes in form and details can be made therein without departing from the spirit and scope of the present invention as defined by the following claims.

What is claimed is:

1. A method of bonding a display device, the method comprising:
forming a seal portion between a substrate, on which an emission region is formed, and an encapsulating part mounted facing the substrate;
aligning positions of the substrate and the encapsulating part in a chamber;
changing a vacuum state of the chamber to an atmospheric pressure state so as apply bonding pressure to the substrate and the encapsulating part, wherein the vacuum state and the atmospheric pressure state have different pressures; and
applying energy to the seal portion so as to bond the substrate and the encapsulating part.

2. The method of claim 1, wherein the seal portion is formed of any one selected from organic adhesive, an organic pressure sensitive adhesive, a metal film, an oxide, a sulfide, a nitride, an organic sulfur compound, an organic silicon compound, and a combination thereof.

3. The method of claim 1, wherein the bonding pressure and the energy are substantially simultaneously applied.

4. The method of claim 1, wherein the seal portion is activated by applying the energy before or when the bonding is performed.

5. The method of claim 1, wherein the energy is applied by irradiating an energy beam to the seal portion.

6. The method of claim 1, wherein the energy is applied by heating the seal portion.

7. The method of claim 1, wherein the substrate comprises any one selected from a glass substrate, a polymer substrate, a flexible film substrate, a metal substrate, and a composite substrate thereof.

8. The method of claim 1, wherein the encapsulating part comprises a flexible film.

9. The method of claim 1, wherein the encapsulating part comprises:
a base film comprising a polymer; and
at least one inorganic layer and at least one organic layer stacked on one surface of the base film.

10. The method of claim 1, wherein, when the bonding pressure inside the chamber is insufficient to bond the substrate and the encapsulating part, pressure inside the chamber is raised so as to increase bonding pressure.

11. The method of claim 1, wherein the bonding pressure is applied to the entire substrate and the entire encapsulating part when a press jig presses a surrounding part of the substrate and the encapsulating part.

12. The method of claim 11, wherein a mask having a pattern is further mounted on the encapsulating part, and
wherein the energy is selectively applied to the seal portion through the pattern.

13. The method of claim 1, wherein the bonding pressure is applied to the entire substrate and the entire encapsulating part when a diaphragm presses the entire substrate and the entire encapsulating part.

14. The method of claim 13, wherein the diaphragm i) has a size for accommodating the substrate and the encapsulating part and ii) presses an entire upper surface of the encapsulating part while the bonding pressure is being applied.

15. The method of claim 13, wherein the diaphragm is formed of a material having an elastic force.

16. The method of claim 1, wherein the seal portion is formed in a non-emission region extending outside the emission region on the substrate.

17. The method of claim 16, wherein the emission region and the seal portion on the substrate are formed with different thicknesses, and
wherein the encapsulating part comprises a flexible film and is directly bonded to the seal portion by using the flexibility of the flexible film to compensate for the different thicknesses.

18. The method of claim 1, wherein a plurality of display devices are manufactured with the substrate, and wherein the substrate is cut into individual display devices after the bonding between the substrate and the encapsulating part is completed.

19. A method of bonding a display device, the method comprising:
forming a seal portion between a substrate and an encapsulating part;
aligning positions of the substrate and the encapsulating part in a chamber;
changing an amount of pressure of the chamber to an atmospheric pressure so as apply bonding pressure to the substrate and the encapsulating part; and
applying energy to the seal portion so as to bond the substrate and the encapsulating part, wherein the bonding pressure and the energy are substantially simultaneously applied.

20. The method of claim 19, wherein the encapsulating part comprises a flexible film.
